(19) United States
(12) Patent Application Publication
(10) Pub. No.: US 2026/0237605 A1
(43) Pub. Date: Aug. 13, 2026

(54) PLASMA GENERATION AND PLASMA-ENHANCED ATOMIC LAYER DEPOSITION DEVICE

(71) Applicant: Truth Equipment Co., LTD, Hefei (CN)

(72) Inventors: Houyi Cheng, Hefei (CN); Yinchang Du, Hefei (CN); Lei Chen, Hefei (CN); Jian Wang, Hefei (CN); Yuting Li, Hefei (CN)

(21) Appl. No.: 19/637,916

(22) Filed: Apr. 2, 2026

(30) Foreign Application Priority Data
Aug. 12, 2025 (CN) 202511121389X

(51) Int. Cl. H01J 37/32; C23C 16/455

(52) U.S. Cl. CPC H01J 37/3211; C23C 16/45536; H01J 2237/3321

(57) ABSTRACT

The present disclosure provides a plasma generation apparatus and a plasma-enhanced atomic layer deposition device. The plasma generation apparatus includes a plasma generation module and a variable pitch module. The plasma generation module includes a reaction tube and a coil disposed around an outer circumference of the reaction tube. The variable pitch module includes a plurality of movable sliders, and the coil is connected to the sliders such that each wrapped turn of the coil is driven to move with movement of the sliders. The variable pitch module changes a spacing between turns of the coil to adjust intensity of an induced magnetic field, thereby changing characteristics and induction efficiency of plasma. The variable pitch module further adjusts an overall position of the coil to change a height between the coil and a sample, thereby affecting density of plasma reaching the sample and improving process flexibility.

### TECHNICAL FIELD

The present disclosure relates to the technical field of semiconductors and pan-semiconductor atomic layer deposition devices, and in particular, to a plasma generation apparatus and a plasma-enhanced atomic layer deposition device.

### BACKGROUND

The plasma-enhanced atomic layer deposition device is a common thin film deposition device, and is widely applied to fields such as semiconductors, pan-semiconductors, optics, and biological medicine due to accurate sedimentation rate, low substrate damage, and high deposition uniformity. However, in an existing device, it is difficult to adjust a plasma coil, which limits process flexibility of the device: inability to adjust the plasma coil means that it is difficult to optimize characteristics of plasma according to different materials and process requirements in a deposition process. For example, different precursors and substrate materials may require plasma with different intensities and energies to achieve an optimal deposition effect, and a non-adjustable coil limits space for optimizing a process parameter. In addition, it is difficult to adjust the plasma coil, and it is difficult to optimize quality of a thin film: the characteristics of the plasma directly affect a growth rate, uniformity, and quality of the thin film. The non-adjustable plasma coil may cause uneven distribution of the plasma on a substrate, to affect uniformity and consistency of the thin film, especially on a large-area substrate or a substrate in a complex geometric shape.

### SUMMARY

The present disclosure provides a plasma generation apparatus and a plasma-enhanced atomic layer deposition device, to solve a problem that it is difficult to adjust a plasma coil in an existing plasma-enhanced atomic layer deposition device.

To achieve the foregoing objective, the present disclosure provides the following technical solutions:

According to one aspect, a plasma generation apparatus is provided, comprising: a plasma generation module and a variable pitch module.

The plasma generation module includes a reaction tube and a coil, and the coil is disposed around the outer circumference of the reaction tube.

The variable pitch module includes several movable sliders, each turn of the coil disposed around the outer circumference of the reaction tube is correspondingly connected to one slider, alternatively, two sliders are disposed on opposite sides of each turn of the coil disposed around the outer circumference of the reaction tube.

Each wrapped turn of coil is driven to move when the slider moves, to change the spacing between turns of the coil or the height thereof.

As a further improvement, the slider is connected to a worm, several spiral lead grooves are provided on the worm, and each slider is correspondingly connected to one spiral lead groove by using a guide block; and the sliders are driven to move in different strokes when the worm rotates.

As a further improvement, one end of the reaction tube is hermetically connected to a vent flange, and the other end is hermetically connected to a water-cooled flange.

A vent valve is connected to the vent flange and is configured to supply a source gas.

A flange opening that is communicated with an inner cavity of the reaction tube is provided on the water-cooled flange.

As a further improvement, a shielding housing is sleeved over the outer side of the reaction tube; a first opening is provided on one side of the shielding housing, to allow the slider to pass through; and a second opening is provided on the other side, to allow two ends of the coil to pass through.

The two ends of the coil extend out to the outer side of the shielding housing, and are connected to a clamping assembly; the clamping assembly includes a clamping bracket and two clamps slidably connected to the clamping bracket; and the two ends of the coil are respectively connected to the clamps.

This application further provides a plasma-enhanced atomic layer deposition device, including the plasma generation apparatus, further including an inlet chamber, a primary cavity, and a secondary cavity that are sequentially disposed at one end of the reaction tube and are coaxial with the reaction tube, and further including a heating assembly, where one end of the heating assembly is supported at one end of the secondary cavity, and the other end of the heating assembly penetrates through the other end of the secondary cavity and extends into the primary cavity.

As a further improvement, a heating disk is disposed at one end of the heating assembly that is located in the primary cavity, a secondary back gas channel is provided on an upper side of the heating disk, the secondary back gas channel is communicated with a primary back gas channel, and the primary back gas channel is provided on a support rod of the heating assembly.

As a further improvement, an insulating ring is mounted on an upper side of the heating disk, and a conductive disk is mounted on an upper side of the insulating ring.

As a further improvement, an inlet pipeline is connected to the inlet chamber.

As a further improvement, a side cavity that can be opened is disposed on one side of the primary cavity, a needle valve is mounted above the side cavity, and an opening of the needle valve is disposed close to a connection between the primary cavity and the side cavity.

As a further improvement, one side of the secondary cavity is sequentially connected to a butterfly valve, a gate valve, and a molecular pump.

Compared with the existing technology, the technical solutions provided by the present disclosure have the following beneficial effects:

(1) According to the plasma generation apparatus of the present disclosure, because different deposition processes require different densities and intensities of plasma, the variable pitch module changes a spacing between turns of the coil, thereby changing intensity of an induced magnetic field, and changing characteristics, induction efficiency, and the like of plasma by using the intensity of the induced magnetic field. The variable pitch module can further adjust a position of the coil as a whole, so as to change a height between the coil and a sample, thereby affecting density of the plasma that reaches the sample. Process flexibility is improved, so that a user can flexibly adjust intensity, energy distribution, and density of the plasma according to different process requirements (for example, different precursors, substrate materials, or deposition rate requirements). Process adaptability and a thin film quality optimization capability of a device are significantly improved.

(2) According to the plasma generation apparatus of the present disclosure, the coil is disposed around the reaction tube, to facilitate adjusting a position of the coil.

(3) According to the plasma generation apparatus of the present disclosure, the clamping bracket and the clamps are additionally disposed, to facilitate fixing of the coil after the position of the coil is adjusted.

(4) According to the plasma-enhanced atomic layer deposition device of the present disclosure, a multi-section distribution is adopted above and below the deposition device, and the plasma generation apparatus, the inlet chamber, the primary cavity, and the secondary cavity are separately and coaxially disposed from top to bottom. A precursor gas may enter from the inlet pipeline and flow to a sample downward. The plasma flows downward from the plasma generation apparatus to the sample. In an aspect, the structure is simple, and in another aspect, the precursor gas and the plasma flow to the sample without hindrance, thereby improving a utilization rate of a precursor material and reducing material waste.

(5) The plasma-enhanced atomic layer deposition device of the present disclosure can be compatible with a plurality of process modes. The heating assembly enables the device to simultaneously support a plurality of process modes such as thermal deposition and plasma-enhanced deposition, and the user may select a most appropriate process according to a specific requirement, thereby improving universality of the device.

(6) According to the plasma-enhanced atomic layer deposition device of the present disclosure, the side cavity is disposed, the needle valve is mounted above the side cavity, and the opening of the needle valve is disposed close to the connection between the primary cavity and the side cavity. During depositing, a gas that is compatible with a deposition material is introduced through the needle valve to form a gas shield between the primary cavity and the side cavity, to prevent the precursor gas from being diverted to one side of the side cavity to generate a large amount of accumulation.

### BRIEF DESCRIPTION OF THE DRAWINGS

FIG. 1 is a schematic diagram of an overall structure of a deposition device.

FIG. 2 is a schematic diagram of an overall structure of a deposition device from another perspective.

FIG. 3 is a cross-sectional view of an overall structure of a deposition device.

FIG. 4 is a schematic diagram of a heating assembly.

FIG. 5 is an enlarged cross-sectional view of A-A of a heating assembly.

FIG. 6 is a top view of a heating disk.

FIG. 7 is a schematic structural diagram of a heating assembly in another case.

FIG. 8 is an enlarged view of a portion A of the heating assembly in FIG. 7.

FIG. 9 is a schematic diagram of a plasma generation module.

FIG. 10 is a schematic diagram of a plasma generation module from another perspective.

FIG. 11 is a cross-sectional view of a plasma generation module.

FIG. 12 is a schematic diagram of an interior of a plasma generation module.

### Description of the numbers:

100, sample;

1, molecular pump; 2, gate valve; 3, butterfly valve; 4, secondary cavity; 5, primary cavity; 501, side cavity; 502, needle valve; 6, inlet chamber; 601, inlet pipeline;

7, plasma generation module; 701, shielding housing; 702, first opening; 703, second opening; 704, reaction tube; 705, water-cooled flange; 7051, flange opening; 7052, cooling pipe; 707, coil; 708, vent valve; 709, vent flange; 710, connecting screw;

8, variable pitch module; 801, slider; 9, heating assembly; 901, heating disk; 9011, primary back gas channel; 9012, first secondary back gas channel; 9013, second secondary back gas channel; 902, retaining ring; 903, insulating ring; 904, conductive disk;

101, clamping bracket; and 102, clamp.

### DETAILED DESCRIPTION

To further understand content of the present disclosure, the present disclosure is described in detail with reference to accompanying drawings and embodiments.

A structure, a proportion, a size, and the like drawn in the accompanying drawings in this specification are only used to cooperate with content disclosed in the specification for those familiar with the technology to understand and read, are not intended to limit limitation conditions under which the present disclosure can be implemented, and do not have technical substantive meaning. Any modification of the structure, change of a proportion relationship, or adjustment of the size still fall within the scope that can be covered by technical content disclosed by the present disclosure without affecting the efficacy and the purpose that can be achieved by the present disclosure.

It is to be noted that in this specification, claims, and accompanying drawings of this application, terms "first", "second", and the like are intended to distinguish similar objects but do not necessarily indicate a specific order or sequence. It is to be understood that data used in such a way may be exchanged under appropriate conditions, so as to implement the embodiments of this application described here.

In this application, an orientation or position relationship indicated by terms such as "upper", "lower", "left", "right", "front", "rear", "top", "bottom", "inner", "outer", "middle", "vertical", "horizontal", "transverse", and "longitudinal" is based on an orientation or position relationship shown in the accompanying drawings. These terms are mainly intended to better describe this application and embodiments thereof, and are not intended to limit that an indicated apparatus, element, or component needs to have a specific orientation, or be constructed and operated in a specific orientation. In addition, some of the foregoing terms may be used to represent another meaning in addition to representing an orientation or position relationship. For example, the term "upper" may alternatively be used to represent a dependency relationship or a connection relationship in some cases. A person of ordinary skill in the art may understand specific meanings of these terms in this application according to specific situations.

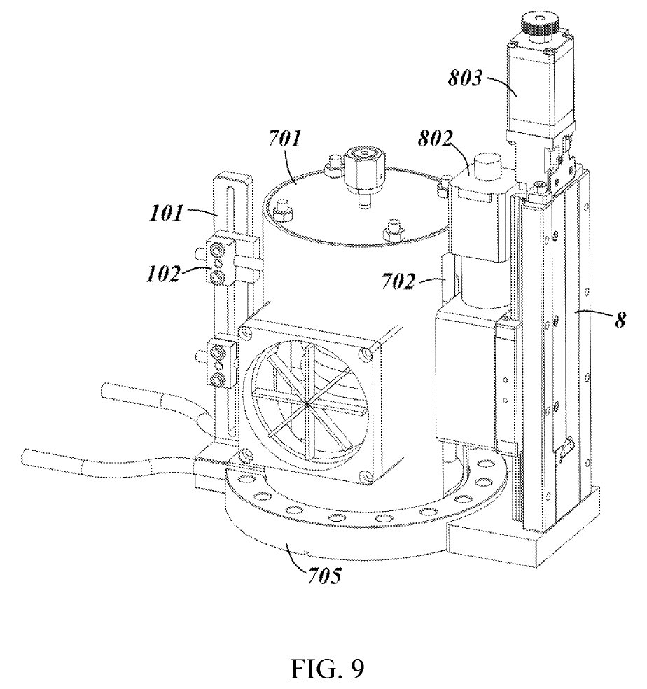

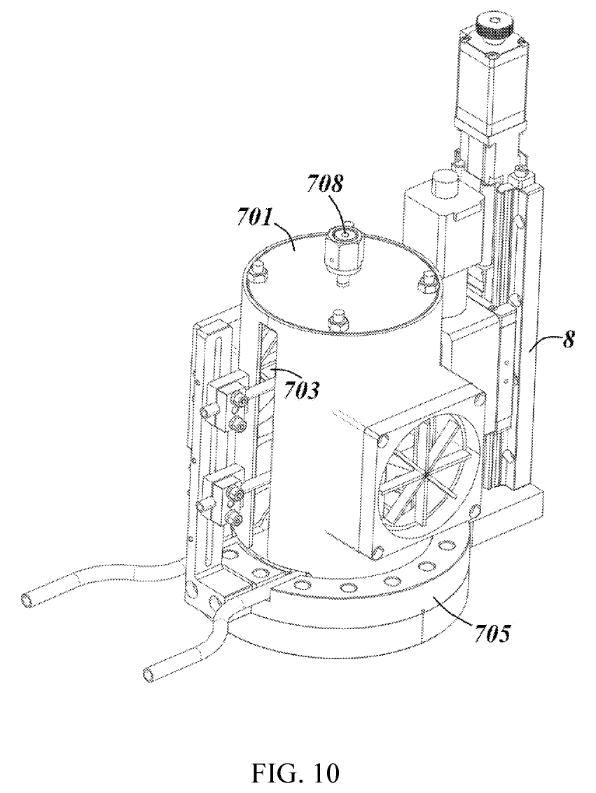

As shown in FIG. 9 to FIG. 12, this embodiment provides a plasma generation apparatus, applied to a thin film deposition device, and including a plasma generation module 7 and a variable pitch module 8.

The plasma generation module 7 includes a reaction tube 704 and a coil 707, and the coil 707 is disposed around the outer circumference of the reaction tube 704. The variable pitch module 8 includes several movable sliders 801, and the coil 707 disposed around the outer circumference of the reaction tube 704 is connected to the slider 801. Each wrapped turn of coil is driven to move when the slider 801 moves, to change the spacing between turns of the coil or the height thereof 707.

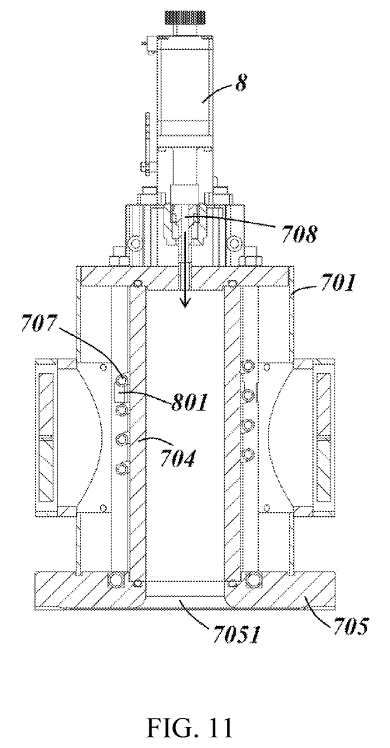

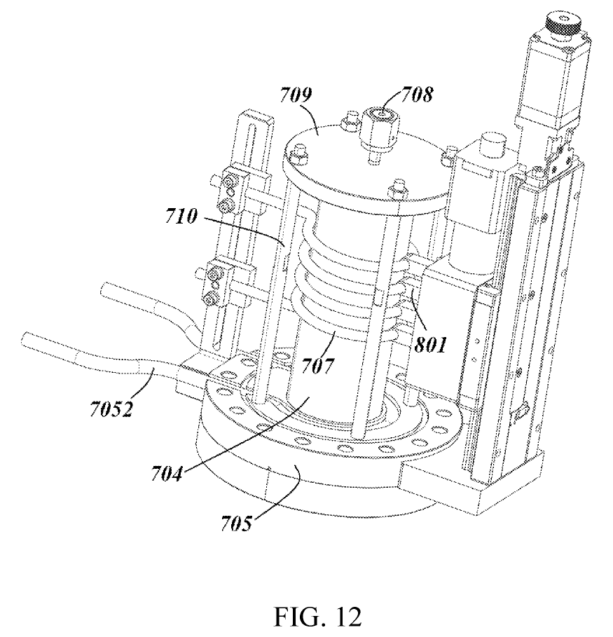

In this embodiment, as shown in FIG. 12, each turn of the coil 707 disposed around the outer circumference of the reaction tube 704 is correspondingly connected to one slider 801. However, in some other embodiments, as shown in FIG. 11, one slider 801 is correspondingly disposed on each of two sides of each turn of the coil 707 disposed around the outer circumference of the reaction tube 704.

Specifically, in this embodiment, the reaction tube 704 is a quartz tube having a cavity therein. Four turns of coil are disposed around the outer circumference of the reaction tube 704. Each turn of the coil 707 is correspondingly connected to one slider 801. Four sliders 801 are disposed in the variable pitch module 8.

In the thin film deposition device, a source gas is introduced into the reaction tube 704, a radio frequency signal is introduced into the coil 707 serving as an induction coil, and a high-frequency alternating magnetic field is generated in the reaction tube 704 around which the coil 707 is wrapped. The source gas accelerates free electrons in an induced magnetic field, so that the source gas obtains sufficient energy to collide with gas molecules, thereby ionizing the gas, and generating plasma. Because different deposition processes require different densities and intensities of plasma, each turn of the coil 707 is correspondingly connected to one slider 801. Each wrapped turn of coil is driven to move when the slider 801 moves, to change a spacing between turns of the coil, thereby changing intensity of the induced magnetic field, and changing characteristics, induction efficiency, and the like of plasma by using the intensity of the induced magnetic field. In addition, the variable pitch module 8 can further adjust a position of the coil 707 as a whole, so as to change a height between the coil 707 and a sample 100, thereby affecting density of the plasma that reaches the sample.

With reference to FIG. 9 to FIG. 12, the variable pitch module 8 further includes a base, a variable pitch assembly 802, and a lifting assembly 803. The lifting assembly 803 is mounted on the base, and the variable pitch assembly 802 is connected to the lifting assembly 803. Specifically, the lifting assembly 803 includes a slide track and a lifting slider that moves along the slide track. The lifting slider is vertically mounted on the base. The variable pitch assembly 802 is driven to move up and down when the lifting slider moves, so that a height between the coil 707 and the sample 100 is changed by using the lifting assembly 803, thereby affecting a density of plasma that reaches the sample. In another aspect, the variable pitch assembly 802 includes four sliders 801, each slider 801 is mounted on a guide rod that is disposed vertically, a guide block is further connected to the slider 801, and the other end of the guide block is connected to a worm. Specifically, four spiral lead grooves are provided on the worm. When the worm rotates, the guide block moves along the spiral lead grooves, so as to drive the slider 801 to slide along the guide rod and change the spacing between the sliders 801. A pitch between turns of the coil is changed by using the slider 801, thereby changing the Faraday electromagnetic induction intensity generated by the coil 707. When the lifting assembly 803 drives the variable pitch assembly 802 to move up and down, the slider 801 is driven to move to change a height of the coil 707.

As shown in FIG. 12, one end of the reaction tube 704 is hermetically connected to a vent flange 709, and the other end is hermetically connected to a water-cooled flange 705. A vent valve 708 is connected to the vent flange 709 and is configured to supply a source gas; and a flange opening 7051 that is communicated with an inner cavity of the reaction tube 704 is provided on the water-cooled flange 705.

Grooves configured to mount sealing rings are disposed at positions where the vent flange 709 and the water-cooled flange 705 are respectively in contact with the two ends of the reaction tube 704, and the sealing rings are mounted in the grooves. The vent flange 709 is connected to the water-cooled flange 705 by using a connecting screw 710, and the reaction tube 704 is located between the vent flange 709 and the water-cooled flange 705. When the connecting screw 710 is screwed, the reaction tube 704 and the vent flange 709 press the sealing ring, and the reaction tube 704 and the water-cooled flange 705 press the sealing ring, so that one end of the reaction tube 704 is hermetically connected to the vent flange 709, and the other end is hermetically connected to the water-cooled flange 705.

A cooling pipe 7052 is further mounted on the water-cooled flange 705, and a cooling liquid is introduced into the cooling pipe 7052 to cool the water-cooled flange 705. In addition, the base in the variable pitch module 8 is further fixedly mounted on the water-cooled flange 705, so as to support and fix the variable pitch module 8.

With reference to FIG. 9 and FIG. 12, a shielding housing 701 is sleeved over and connected to an outer side of the reaction tube 704. A first opening 702 is provided on one side of the shielding housing 701, to allow the slider 801 to pass through; and a second opening 703 is provided on the other side, to allow two ends of the coil 707 to pass through.

After wrapping around the reaction tube 704, the two ends of the coil 707 extend out to an outer side of the shielding housing 701 through the second opening 703 and are connected to the clamping assembly; the clamping assembly includes a clamping bracket 101 and two clamps 102 that are slidably connected to the clamping bracket 101; and the two ends of the coil 707 are respectively connected to the clamps 102. The clamping bracket 101 is fixed to the water-cooled flange 705. The clamp 102 includes a clamping base and a clamping block. The clamping base is mounted on the clamping bracket 101, the clamping block is locked to the clamping base by using a bolt, and the coil 707 may be clamped between the clamping base and the clamping block. A position of the clamping base on the clamping bracket 101 may be adjusted. In an aspect, a distance between the two clamps 102 is changed, and a spacing between turns of the coil is adjusted in cooperation with the slider 801. In another aspect, heights of the two clamps 102 may be simultaneously adjusted, and the height of the coil 707 is adjusted in cooperation with the lifting assembly 803.

It is to be further noted that, in some other embodiments, when one slider 801 is correspondingly disposed on each of two sides of each turn of the coil 707 disposed around the outer circumference of the reaction tube 704, a shape of the slider 801 may be set to an arc shape. The arc-shaped slider 801 can match the outer side of the reaction tube 704, and can have more contact area with the coil 707 when moving, so as to facilitate adjusting the spacing of the coil.

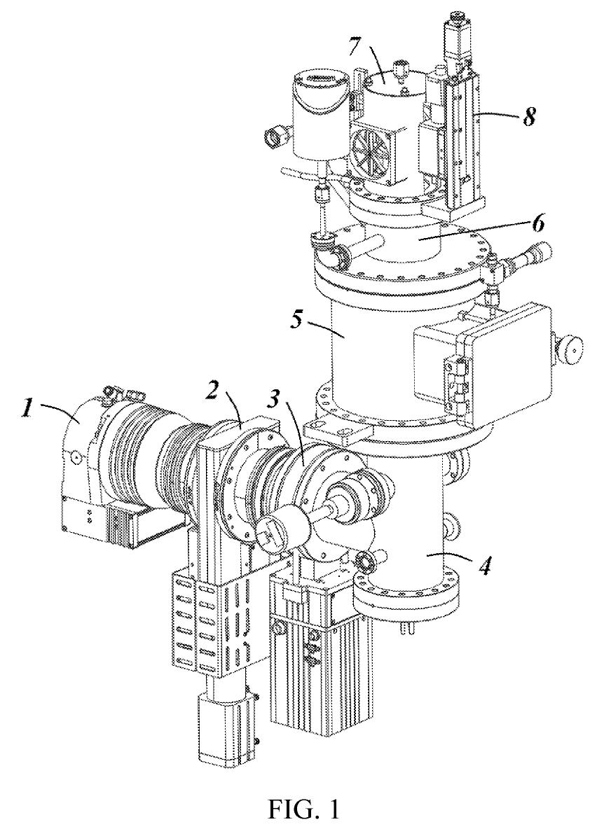

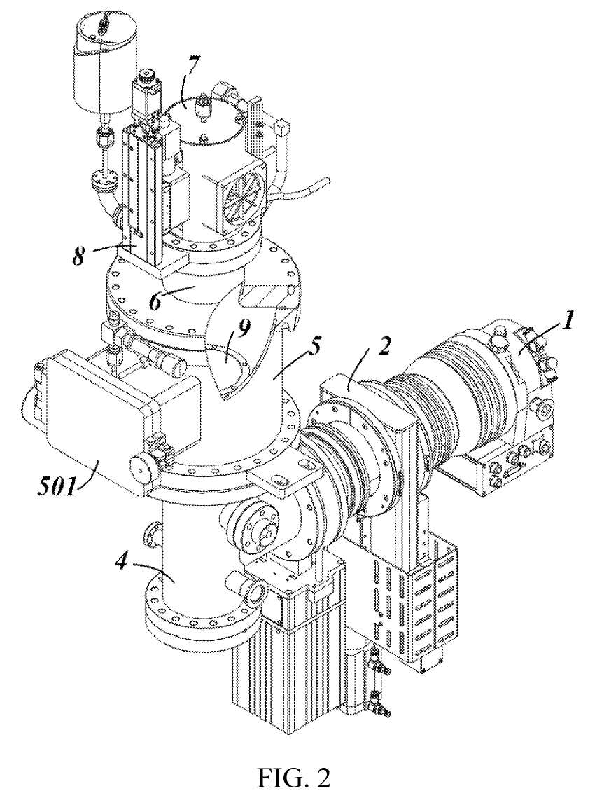

As shown in FIG. 1 to FIG. 3, this application further provides a plasma-enhanced atomic layer deposition device, including the plasma generation apparatus, and further including an inlet chamber 6, a primary cavity 5, and a secondary cavity 4 that are sequentially disposed at one end of the reaction tube 704 and are coaxial with the reaction tube 704. Specifically, a lower end of the reaction tube 704 is hermetically connected to the inlet chamber 6 by using a connecting flange, a flange opening 7051 is provided on the water-cooled flange 705, and an opening is similarly provided on the connecting flange at this position, so that an inner cavity of the reaction tube 704 is communicated with an inner cavity of the inlet chamber 6. A lower end of the inlet chamber 6 is similarly hermetically connected to the primary cavity 5 by using a flange, and an opening is similarly provided on the flange, so that the inner cavity of the inlet chamber 6 is communicated with an inner cavity of the primary cavity 5. A lower end of the primary cavity 5 is similarly hermetically connected to the secondary cavity 4 by using a flange, and an opening is similarly provided on the flange, so that the inner cavity of the primary cavity 5 is communicated with an inner cavity of the secondary cavity 4.

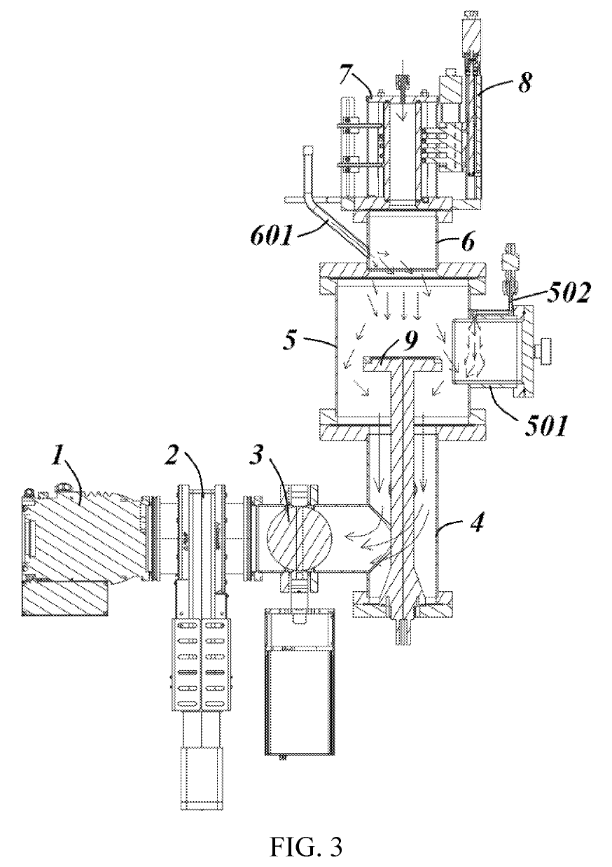

The deposition device further includes a heating assembly 9. One end of the heating assembly 9 is supported and connected to a lower end of the secondary cavity 4, and the other end of the heating assembly 9 penetrates through an upper end of the secondary cavity 4 and extends into the primary cavity 5 (described in a view orientation in FIG. 3).

The heating assembly 9 includes a support rod and a heating disk 901. One end of the support rod is supported at the lower end of the secondary cavity 4, and the heating disk 901 is located at the other end of the support rod. The support rod penetrates through the secondary cavity 4 and extends into the primary cavity 5, and the support rod can guide a gas. Specifically, the heating disk 901 is disposed at one end of the heating assembly 9 that is located in the primary cavity 5. A secondary back gas channel is provided on an upper side of the heating disk 901. The secondary back gas channel is communicated with a primary back gas channel 9011. The primary back gas channel 9011 is provided at a center of the support rod of the heating assembly 9.

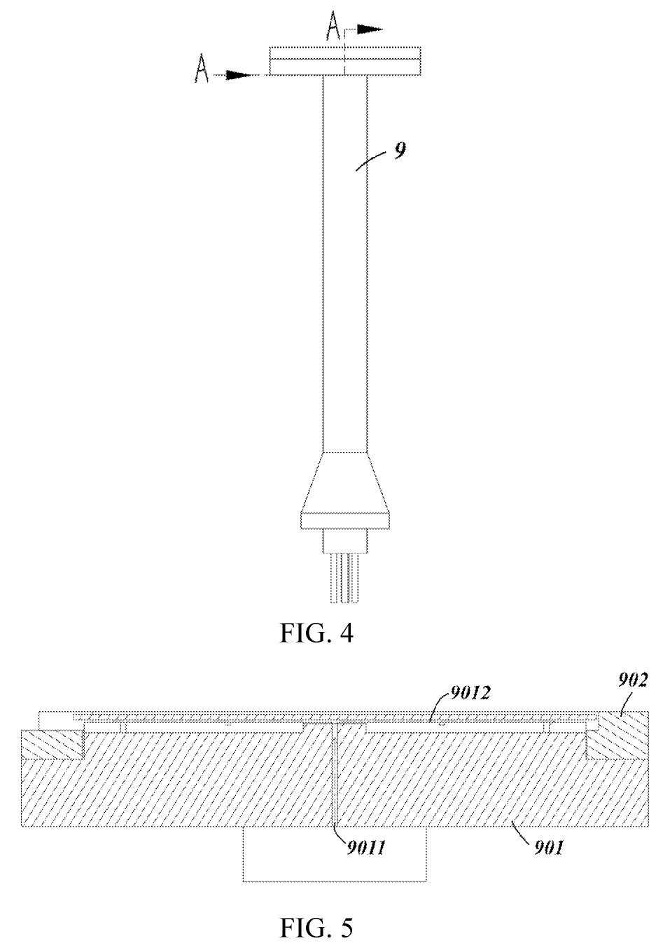

With reference to FIG. 4, FIG. 5, and FIG. 6, the secondary back gas channel includes several linear first secondary back gas channels 9012 and several circular arc-shaped second secondary back gas channels 9013. The first secondary back gas channel 9012 is disposed in a radial direction of the heating disk 901 and is communicated with the primary back gas channel 9011. The second secondary back gas channel 9013 is disposed in a peripheral direction of the heating disk 901 and is communicated with the first secondary back gas channel 9012.

The heating assembly 9 is mainly configured to heat a sample, or apply a bias voltage to the sample to perform cleaning or assist in depositing.

During heating, the sample 100 is placed on the heating disk 901. A heating wire is further distributed on the heating disk 901, to heat an upper surface of the heating disk 901. A cooling channel is further provided in the heating disk 901, to stabilize a temperature of the heating disk 901 and cool the heating disk 901. Due to an impact of processing precision, the heating disk 901 cannot be completely adhered to the sample 100. Usually, the heating disk 901 is in multi-point contact with the sample 100 to achieve heat conduction between the heating disk 901 and the sample 100. The primary back gas channel 9011 and the secondary back gas channel having diameters of approximately 0.5 mm are disposed at the upper surface of the heating disk 901, to uniformly heat and cool the sample 100 placed above. A gas flows in through the primary back gas channel 9011, is dispersed through the secondary back gas channel, and is uniformly distributed to a back of the sample 100. The heating disk 901 heats the sample with reference to the gas, to uniformly heat and cool the sample. In addition, a step groove is further provided on an outer periphery of the heating disk 901, and a retaining ring 902 is mounted in the step groove. When a back gas is introduced into the heating disk 901, because the gas has a pressure, there is displacement at a contact surface between the sample 100 and the heating disk 901, and the retaining ring 902 needs to be added to radially limit the sample. An upper surface of the retaining ring 902 extends beyond the sample by 1 to 2 mm. In practice, when back gas with a proper pressure and flow rate is introduced to the back of the sample 100, the sample 100 is separated from the heating disk 901 by approximately 0 to 0.5 mm. In this case, a sample position may be well restricted by using the retaining ring 902.

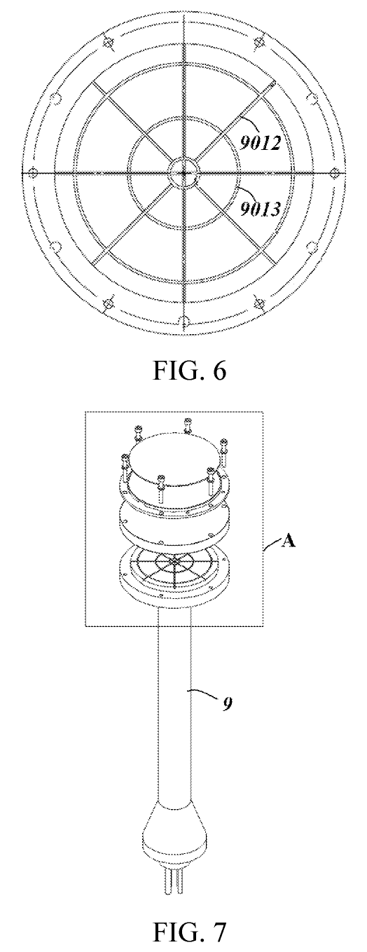

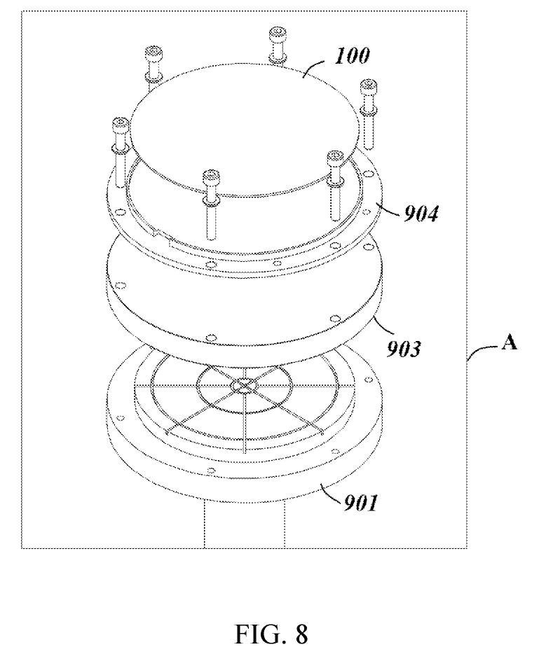

With reference to FIG. 7 and FIG. 8, in another aspect, when a bias voltage needs to be applied to the sample, the back gas is not introduced into the back gas channel of the heating disk 901. In this case, the retaining ring 902 is removed from the heating assembly 9. An insulating ring 903 is mounted on an upper side of the heating disk 901, and a conductive disk 904 is mounted on an upper side of the insulating ring 903. Specifically, the insulating ring 903 is adhered to an upper surface of the heating disk 901, and is configured for heat transfer of the heating disk 901. The insulating ring 903 needs to select a material having a relatively high thermal conductivity, for example, alumina ceramics or 304 stainless steel, and the thermal conductivity of the insulating ring 903 can reach 20 to 30 W/(m.k). Heat of the heating disk 901 may be relatively well transferred by using the material having the high thermal conductivity. A conductive disk 904 is disposed on an upper portion of the insulating ring 903, the conductive disk is made of a conductive metal material, and a sample is placed in the middle of the conductive disk 904. The insulating ring 903 and the conductive disk 904 may be fixedly connected to the heating disk 901 by bolts.

The sample 100 is located on the conductive disk 904. The conductive disk 904 is connected to a radio frequency electrode by using a vacuum wire. A radio frequency signal is introduced through the radio frequency electrode, and is introduced from the radio frequency electrode to the conductive disk 904 by using a wire connection, so that the conductive disk 904 is charged. Further, the radio frequency signal is transferred to the sample 100 placed above, so that the sample 100 is charged and a bias voltage is generated on the sample 100.

With reference to FIG. 6, in this application, an inlet pipeline 601 is connected to the inlet chamber 6. The inlet pipeline 601 is configured to introduce a precursor gas. Preferably, the inlet pipeline 601 is obliquely disposed relative to an axial center of the inlet chamber 6, so as to facilitate flow of the precursor gas toward the sample after being introduced.

A side cavity 501 that can be opened is disposed on one side of the primary cavity 5, and a sample is placed in the primary cavity 5 through the side cavity 501. Further, a needle valve 502 is mounted above the side cavity 501, and an opening of the needle valve 502 is disposed close to a connection between the primary cavity 5 and the side cavity 501.

One side of the secondary cavity 4 is sequentially connected to a butterfly valve 3, a gate valve 2, and a molecular pump 1. Specifically, the butterfly valve 3 is connected to the secondary cavity 4, the butterfly valve 3 is connected to the gate valve 2, and the gate valve 2 is connected to the molecular pump 1.

Specifically, the primary cavity 5 is a cylindrical vacuum sealed cavity, and is made of a corrosion-resistant 316L material. CF200 metal sealed interfaces are symmetrically disposed above and below for connecting the secondary cavity 4 and the inlet chamber 6 (CF represents a sealed interface standard specifically designed for a vacuum system, and is commonly seen in a vacuum pipeline connection). The two CF interfaces are compressed and sealed by using a metal gasket. The metal gasket has excellent corrosion resistance, and can withstand a high temperature. A cavity part needs to be heated to 200 to 300 °C in a thin film depositing process. The side cavity 501 is configured for apparatus maintenance and sample placement inside the cavity. Because of the disposition of the side cavity 501, when the precursor gas enters the side cavity from a top, a relatively large quantity of materials may be stacked on one side of the sample close to the side cavity 501, thereby affecting a thickness of a thin film close to the sample on the side and film thickness uniformity of the whole sample. A needle valve 502 is mounted above the side cavity 501, and an opening of the needle valve 502 is disposed close to a connection between the primary cavity 5 and the side cavity 501. During depositing, a gas that is compatible with a deposition material is introduced through the needle valve 502 to form a gas shield between the primary cavity 5 and the side cavity 501, to prevent the precursor gas from being diverted to one side of the side cavity 501 to generate a large amount of accumulation. An opening of the side cavity 501 is connected to a cavity door by using a hinge. When the cavity door is closed, to implement vacuum sealing, sealing rings are mounted on the periphery of the cavity door.

An expansion interface is provided on a side portion of the secondary cavity 4 to connect to the butterfly valve 3. The secondary cavity 4 is further connected to a vacuum gauge for monitoring a vacuum pressure inside. The secondary cavity 4 is further connected to a radio frequency electrode, and the radio frequency electrode is configured to be connected to the conductive disk 904. The butterfly valve 3 is configured to control a vacuum pressure in each vacuum cavity (the butterfly valve stably controls a pressure in the cavity by controlling opening and closing of a valve plate), and the other side of the butterfly valve 3 is connected to the gate valve 2 for isolating a vacuum environment in each cavity to be independent. The other side of the gate valve 2 is connected to a molecular pump 1 to achieve a higher vacuum atmosphere in the cavity, so that the vacuum in the cavity is better, and there are fewer impurity gases in the cavity, thereby ensuring a more stable process. A bottom of the secondary cavity 4 is hermetically connected to a flange, the flange is hermetically connected to the heating assembly 9, and an axial center of the heating assembly 9 coincides with an axial center of the secondary cavity 4.

An upper portion of the primary cavity 5 is connected to the inlet chamber 6, the inlet pipeline 601 is connected to the inlet chamber 6, and in addition, a pressure sensor is further connected to the inlet chamber 6 and is configured to monitor a vacuum pressure inside the cavity. In this solution, the vacuum in the cavity is controlled by using the butterfly valve 3, and different processes require different vacuum requirements. For example, a pressure is controlled to be 0.2 to 2 pa when plasma cleaning is performed, and the pressure is controlled to be between 0.1 and 10 pa when the precursor gas is introduced to deposit the thin film.

In this solution, a multi-section distribution is adopted above and below the deposition device, and the plasma generation apparatus, the inlet chamber 6, the primary cavity 5, and the secondary cavity 4 are respectively arranged from top to bottom. A precursor gas may enter from the inlet pipeline 601 and flow to a sample 100 downward. The plasma flows downward from the plasma generation apparatus to the sample 100.

When the butterfly valve 3 is connected to the gate valve 2, and the molecular pump 1 is started, the vacuum inside the cavity meets a process requirement. During thin film depositing, the needle valve 502 is opened, a gas is introduced to block the precursor gas in the primary cavity 5, thereby reducing deposition of the material on one side close to the side cavity 501.

It is to be noted that the inlet chamber 6, the primary cavity 5, and the secondary cavity 4 are connected to each other by using CF sealing flanges. The needle valve 502 is hermetically connected to the side cavity 501, the secondary cavity 4 is hermetically connected to the vacuum gauge, the secondary cavity 4 is hermetically connected to the radio frequency electrode, and the inlet chamber 6 is hermetically connected to the pressure sensor. In addition, in the heating assembly 9, a vent pipeline and a cooling pipeline are similarly hermetically connected to components where the vent pipeline and the cooling pipeline are located. The foregoing hermetically connecting manner may use an existing manner, for example, adding a sealing ring.

When the deposition device in this solution is used, a cavity door of the side cavity 501 is opened to place the sample 100 at an upper portion of the heating assembly 9. The butterfly valve 3, the gate valve 2, and the molecular pump 1 are opened to vaccumize the cavity, and the vacuum is controlled to a high vacuum of - 5 pa.

During sample cleaning, argon with a fixed flow rate is introduced by using the vent valve 708, and a cavity pressure is monitored in real time by using the pressure sensor, thereby fixing a pressure value in the cavity to be between 0.2 and 2 pa. Because different processes require different densities and intensities of plasma, a height of the coil 707 is controlled by using the variable pitch module 8, and intensity and uniformity of the plasma is controlled by controlling a distance from the plasma to the sample 100. In addition, the variable pitch module 8 controls the spacing between turns of the coil 707 to change plasma characteristics, induction efficiency, and the like, and the variable pitch module 8 continuously adjusts parameters to meet a process requirement. After the position adjustment is completed, the coil 707 is connected to a radio frequency power supply, and a high-frequency alternating magnetic field is generated around the coil 707, to generate the plasma. The plasma freely moves to the sample 100 to bombard the sample for cleaning.

When the thin film deposition needs to be performed, if a sample needs to be deposited in a high-temperature state, the temperature of the sample needs to be increased to a process temperature by using the heating assembly 9, and then a precursor gas is introduced through the inlet pipeline 601. A concentration of the precursor gas is determined by monitoring a pressure value of the pressure sensor, so that the sample sufficiently interacts with the precursor gas, and a layer of thin film is deposited on a surface of the sample.

In this solution, the plasma is introduced while depositing the thin film, to as to enhance reaction activity of a precursor, achieve atomic-level film thickness and uniformity accuracy, and improve thin film performance.

Terms "mount", "dispose", "provide", and "connect" mentioned herein is to be understood in a broad sense. For example, the connection may be fixedly connected, detachably connected, or integrally constructed, may be mechanically connected or electrically connected, or may be directly connected, or indirectly connected by using an intermediate medium, or communication between two apparatuses, elements, or composition parts. A person of ordinary skill in the art may understand specific meanings of the foregoing terms in this application according to specific cases.

The present disclosure and implementations thereof are schematically described above, and the description is not restrictive. The accompanying drawings show only one

implementation of the present disclosure, and actual structures are not limited thereto. Therefore, if a person of ordinary skill in the art is inspired by the present disclosure, a structural manner and an embodiment similar to the technical solution without creative design without departing from the spirit of the present disclosure all fall within the protection scope of the present disclosure.

What is claimed is:

1. A plasma generation apparatus, comprising a plasma generation module and a variable pitch module, wherein
the plasma generation module comprises a reaction tube and a coil, and the coil is disposed around the outer circumference of the reaction tube;
the variable pitch module comprises several movable sliders, each turn of the coil disposed around the outer circumference of the reaction tube is correspondingly connected to one slider, alternatively, two sliders are disposed on opposite sides of each turn of the coil disposed around the outer circumference of the reaction tube; and
each wrapped turn of coil is driven to move when the slider moves, to change the spacing between turns of the coil or the height thereof.

2. The plasma generation apparatus according to claim 1, wherein the slider is connected to a worm, several spiral lead grooves are provided on the worm, and each slider is correspondingly connected to one spiral lead groove by using a guide block; and the sliders are driven to move in different strokes when the worm rotates.

3. The plasma generation apparatus according to claim 1, wherein one end of the reaction tube is hermetically connected to a vent flange, and the other end is hermetically connected to a water-cooled flange;
a vent valve is connected to the vent flange and is configured to supply a source gas; and
a flange opening that is communicated with an inner cavity of the reaction tube is provided on the water-cooled flange.

4. The plasma generation apparatus according to claim 3, wherein a shielding housing is sleeved over the outer side of the reaction tube; a first opening is provided on one side of the shielding housing, to allow the slider to pass through; a second opening is provided on the other side, to allow two ends of the coil to pass through;
the two ends of the coil extend out to the outer side of the shielding housing, and are connected to a clamping assembly; the clamping assembly comprises a clamping bracket and two clamps slidably connected to the clamping bracket; and the two ends of the coil are respectively connected to the clamps.

5. A plasma-enhanced atomic layer deposition device, comprising the plasma generation apparatus according to claim 1, further comprising an inlet chamber, a primary cavity, and a secondary cavity that are sequentially disposed at one end of the reaction tube and are coaxial with the reaction tube, and further comprising a heating assembly, wherein one end of the heating assembly is supported at one end of the secondary cavity, and the other end of the heating assembly penetrates through the other end of the secondary cavity and extends into the primary cavity.

6. The plasma-enhanced atomic layer deposition device according to claim 5, wherein a heating disk is disposed at one end of the heating assembly that is located in the primary cavity, a secondary back gas channel is provided on an upper side of the heating disk, the secondary back gas channel is communicated with a primary back gas channel, and the primary back gas channel is provided on a support rod of the heating assembly.

7. The plasma-enhanced atomic layer deposition device according to claim 6, wherein an insulating ring is mounted on an upper side of the heating disk, and a conductive disk is mounted on an upper side of the insulating ring.

8. The plasma-enhanced atomic layer deposition device according to claim 5, wherein an inlet pipeline is connected to the inlet chamber.

9. The plasma-enhanced atomic layer deposition device according to claim 5, wherein a side cavity that can be opened is disposed on one side of the primary cavity, a needle valve is mounted above the side cavity, and an opening of the needle valve is disposed close to a connection between the primary cavity and the side cavity.

10. The plasma-enhanced atomic layer deposition device according to claim 5, wherein one side of the secondary cavity is sequentially connected to a butterfly valve, a gate valve, and a molecular pump.
